(19) United States
(12) Patent Application Publication
(10) Pub. No.: US 2014/0170410 A1
(43) Pub. Date: Jun. 19, 2014

(54) Method for Applying a Coating to a Substrate, Coating, and Use of Particles

(71) Applicants: Markus Rupprecht, Edelsfeld (DE); Christian Wolfrum, Erlangen (DE); Marco Greb, Linsengericht (DE); Eckart Theophile, Wenzenbach (DE)

(72) Inventors: Markus Rupprecht, Edelsfeld (DE); Christian Wolfrum, Erlangen (DE); Marco Greb, Linsengericht (DE); Eckart Theophile, Wenzenbach (DE)

(73) Assignee: ECKART GMBH, Hartenstein (DE)

(21) Appl. No.: 14/234,811

(22) PCT Filed: Jul. 25, 2012
(86) PCT No.: PCT/EP2012/064637

§ 371 Date: Jan. 24, 2014

(30) Foreign Application Priority Data
Jul. 25, 2011 (DE) 10 2011 052 118.6

(51) Int. Cl. C23C 16/513

(52) U.S. Cl. CPC C23C 16/513
USPC 428/327; 427/569; 427/576; 427/578

(57) ABSTRACT

The present invention relates to a method for applying a coating to a substrate using cold plasma, wherein particles provided with a polymer coating are fed into a cold plasma at less than 3,000 K and the particles activated by this are deposited on a substrate. The present invention furthermore relates to a substrate coating which can be obtained by the methods according to the invention. The present invention furthermore relates to the use of platelet-shaped particles with a polymer coating with an average thickness of less than 2 μm in the coating of a substrate using a cold plasma.

The present invention relates to a method and a device for applying a coating to a substrate, in which a plasma jet of a low temperature plasma is generated by passing a working gas through an excitation zone. The invention moreover relates to a coating on a substrate of particles at least partially intergrown with one another. The invention furthermore relates to the use of particles which are enclosed by a shell consisting of a crosslinked polymer.

The production of layers on substrates has been known for a long time and is of great economic interest. A large number of different methods are used, some of which, for process engineering reasons, require reduced pressure, very high gas speeds or high temperatures. In particular, so-called spraying methods are used. A known method is plasma spraying, in which a gas or gas mixture flowing through an arc of a plasma torch is ionized. An electrically conductive gas, heated to a high temperature, with a temperature of up to 20,000 K is produced during the ionization. Powder, usually in a particle size distribution of between 5 and 120 μm, is injected into this plasma jet and is melted by the high plasma temperature. The plasma jet carries the powder particles along and applies them to the substrate to be coated. Plasma coating by the route of plasma spraying can be carried out under normal atmosphere.

The high gas temperatures of above 10,000° C. are necessary in order to be able to melt the powder and thus deposit it as a layer. Plasma spraying is accordingly very expensive in terms of energy, as a result of which an inexpensive coating of substrates is often not possible. Furthermore, expensive apparatuses must be used to generate the high temperatures. Because of the high temperatures, temperature-sensitive and/or very thin substrates, such as polymer films and/or paper, cannot be coated. Such substrates are damaged by the high thermal energy. Expensive pretreatment steps are sometimes necessary in order to ensure a sufficient adhesion of the deposited layers on the surface. It is moreover a disadvantage that during plasma spraying there is a high thermal load of the particles used, as a result of which these can at least partially oxidize, in particular if metallic particles are used. This is a disadvantage in particular if metallic layers which are to be used, for example, for strip conductors or as corrosion protection are to be deposited.

For these reasons methods have been developed which use a so-called atmospheric cold plasma, also called low temperature plasma, in order to produce layers on substrates. In the methods, a cold plasma jet is generated under atmospheric conditions via methods known to a person skilled in the art and a powder is introduced into the plasma jet, which powder is then deposited on the substrate.

From EP 1 230 414 B1 a generic method for applying a coating to a substrate is known, in which a plasma jet of a low temperature plasma is generated under atmospheric conditions by passing the working gas through an excitation zone. A precursor material consisting of monomeric compounds is fed into the plasma jet separately from the working gas. In the case of sensitive precursor materials, the feeding into the relatively cool plasma jet can take place downstream of the excitation zone. As a result of this, a coating of the substrate with precursor materials which are stable only at temperatures of up to 200 degrees Celsius or less is possible.

A disadvantage of this method is that monomeric compounds are fed into a plasma as precursor material and are reacted there, as a result of which only relatively low deposition rates of 300-400 nm/sec can be achieved. These are 10-1,000 times lower than the deposition rates which are achieved in corresponding methods using pulverulent starting materials, even if particles which are present in an order of magnitude of 100 μm are used. Accordingly, an economical coating on an industrial scale is not possible with this method.

From EP 1 675 971 B1 a further method is known for coating a substrate surface using a plasma jet of a low temperature plasma, to which a fine-particled powder in a size of 0.001-100 μm, which forms the coating, is fed by means of a powder conveyor. In deviation from thermal plasmas, the temperature of a low temperature plasma reaches less than 900 degrees Celsius in the core of the plasma jet under ambient pressure. In EP 1 675 971 B1, temperatures in the core of the plasma jet which arises of up to 20,000 degrees Celsius are therefore indicated for thermal plasmas.

The document DE102006061435A1 teaches a method for spraying a track, in particular a strip conductor, onto a substrate, by introducing a powder by means of a carrier gas into a spray lance in which a cold plasma (<3,000 K) is generated, which powder then impinges on a substrate.

In both methods fine-particled powders in sizes of 0.001-100 μm are fed into a cold plasma (<500° C.) and deposited as a layer onto a surface. A disadvantage here of the described methods is that materials with higher melting points, e.g. ceramic materials or high-melting metals, cannot be melted in the process unless particles with a very small average diameter, i.e. for example smaller than 1 μm, are used. The gas flows put into the plasma state and therefore the plasma gas speed is so high in the named methods that the dwell time of the particles in the hot zones of the plasma is not sufficient to achieve a complete through-melting of the particle. In the case of materials with an elevated melting temperature (e.g. Ag, Cu, Ni, Fe, Ti, W), melting therefore occurs at most on the particle surface, and a porous layer forms in which the particles adhere to one another virtually in the starting dimension. The documents therefore describe a preferred use of low-melting metals, such as tin and zinc. The effect that the particles melt at most at their outer shell can be explained by the fact that because of the conditions in the plasma, an activation takes place primarily on the surface. By using very small particles, the specific surface area can be increased, but such powders can be conveyed only with difficulty, with the result that they cannot be used economically on an industrial scale.

The described methods accordingly have fundamental disadvantages. The object of the invention is to provide a method in which a sufficient activation of the particles is achieved with simultaneous good conveyability.

The object is achieved according to the invention by a method with the features of claim 1. The coating of substrates is accordingly carried out with an atmospheric cold plasma into which the material which forms the layer is introduced, for example in the form of particles which are provided with a shell consisting of a crosslinked polymer. Such a shell can be produced, for example, by applying monomers, oligomers, polymers or mixtures of the abovementioned to the surface of the particles and crosslinking them there.

The present invention relates to a method for applying a coating to a substrate using cold plasma, which is characterized in that the method comprises the following steps:

(a) introducing particles provided with a polymer coating into a cold plasma which is directed onto a substrate to be coated and has a plasma temperature of less than 3,000 K,
(b) depositing the particles activated in the cold plasma in step (a) on the substrate.

According to the invention, by “activated particles” is meant that the particles can be applied adhesively to the substrate. The particles can be softened or melted on the surface or completely, in order to adhere to the substrate. However, the particles can also be put into an energy-holding state which makes possible the formation of a physical or chemical bond with the substrate.

In particular embodiments of the abovementioned method the application, preferably spraying on, of the coating to a substrate is carried out using a coating nozzle which extends in a longitudinal direction and is moved or can be moved with a relative speed relative to the substrate, wherein in one plasma zone, which inside an electrode preceding the coating nozzle, a cold plasma with a plasma temperature below 3,000 K is generated, and wherein a powder is introduced into the coating nozzle with the aid of a carrier gas, which powder is carried along by the plasma in the direction towards a front end exit opening out of the coating nozzle, exits there and impinges on the substrate, wherein the powder is constituted by particles with a polymer shell.

In particular embodiments of the abovementioned method the cold plasma is generated in or before a coating nozzle and the particles are introduced into the coating nozzle via a carrier gas, wherein the coating nozzle and the substrate are movable relative to one another. Consequently, the coating nozzle can be arranged movable or can be moved relative to the substrate or the substrate can be arranged movable or can be moved relative to the coating nozzle. The coating nozzle and the substrate can of course also be arranged movable or can be moved relative to one another.

In particular embodiments of the abovementioned methods the average layer thickness of the, preferably enveloping, polymer coating is less than 2 μm.

In particular embodiments of the abovementioned methods the cold plasma is generated under the application of a pulsed direct voltage or alternating voltage to an ionizable gas.

In particular embodiments of the abovementioned methods the particles are platelet-shaped.

In particular embodiments of the abovementioned methods the particles, preferably the platelet-shaped particles, in the plasma zone at least partially react chemically or physically. Preferably, in certain of the abovementioned embodiments the particles at least partially melt.

In particular embodiments of the abovementioned methods the carrier gas is passed through a container, in which the particles are stored as a powder, at a flow rate such that the powder is at least partially swirled up, a powder dust being generated, and the generated powder dust is introduced into the coating nozzle.

In particular embodiments of the abovementioned methods the carrier gas flows through the coating nozzle with a volume flow from a range of from 1 Nl/min to 15 Nl/min, and preferably under pressures of between 0.5 bar and 2 bar. The term “normal liter” or “Nl” within the meaning of the present invention designates the amount of gas which fills a 1-litre spatial volume in the normal state (1013 mbar and 0° C.).

In particular embodiments of the abovementioned methods the cold plasma is generated, and the particles are then applied to the substrate, under a pressure which largely corresponds to atmospheric conditions. Preferably, the pressure in particular embodiments lies in a range of 0.5 10⁵-1.5×10⁵ Pa.

In particular embodiments of the abovementioned methods the average thickness of the, preferably enveloping, polymer coating is less than 300 nm.

In particular embodiments of the abovementioned methods the polymer coating is a polymerized (meth)acrylate resin. In certain of the abovementioned embodiments the polymer coating is preferably a polymerized acrylate resin.

In particular embodiments of the abovementioned methods the particles are metal particles, preferably platelet-shaped metal particles, and the metals are selected from the group which consists of aluminum, zinc, tin, titanium, iron, copper, silver, gold, tungsten, nickel, lead, platinum, silicon and alloys thereof and mixtures thereof.

In particular embodiments of the abovementioned methods the substrate is selected from the group which consists of metals, plastics, paper, biological materials, glass, ceramic and mixtures thereof. Preferably, in certain of the above-mentioned embodiments the substrate is selected from the group which consists of metals, wood, plastics, paper and mixtures thereof.

In particular embodiments of the abovementioned methods the particles coated with a polymer are selected from the group which consists of oxides, carbides, silicates, nitrides, phosphates, sulfates and mixtures thereof.

The present invention furthermore relates to a coating on a substrate, obtainable by a method according to one of the preceding claims.

In particular embodiments of the abovementioned coating, the particles are platelet-shaped metal particles and the coating has platelet-shaped metal particles at least partially intergrown with one another.

In particular embodiments of the abovementioned coatings the coating consists of platelet-shaped metal particles, at least partially intergrown with one another, produced by spraying the coating onto the substrate with the aid of a coating nozzle which extends in the longitudinal direction and which can be moved or is moved with a relative speed relative to the substrate, wherein in one plasma zone, which inside an electrode preceding the coating nozzle, a cold plasma with a plasma temperature below 3,000 K is generated, and wherein a powder is introduced into the coating nozzle with the aid of a carrier gas, which powder is carried along by the plasma in the direction towards a front end exit opening out of the coating nozzle, exits there and impinges on the substrate, wherein

a) before entry into the plasma zone a carrier gas is passed at least partially through a powder with a polymer shell,
b) the powder is introduced into the coating nozzle with the aid of the carrier gas,
c) the powder is carried along by the carrier gas from the plasma in the direction towards a front end exit opening of the coating nozzle, exits there and impinges on the substrate.

The present invention furthermore relates to the use of platelet-shaped particles, preferably of platelet-shaped metal particles, which have a polymer coating with an average thickness of less than 2 μm in the application of a coating to a substrate using cold plasma.

The production of layers on substrates by using powders and cold atmospheric plasma requires an interplay between plasma and particles. While the parameters of the plasma are known to a person skilled in the art from the state of the art, the requirements on the powder are usually predetermined by the use. Thus, particular materials are required for particular uses. For example, a prerequisite of the production of conductive layers is the use of powders of conductive materials.

A person skilled in the art is therefore usually limited in the choice of materials by the objective of the use. However, he can choose the powder parameters freely. An essential parameter which determines the properties of the powder is the diameter of the powder particles. As a rule a simple diameter cannot be indicated for a particular powder, rather the diameter has a distribution. This distribution is as a rule characterized by indicating D values, for example the D50 value. These D values can be determined by means of laser granulometry, for example with HELOS or CILAS apparatuses. In the case of the D₅₀ value, 50% of the abovementioned particle size distribution volume-averaged by means of laser granulometry lies below the indicated value.

In this method, the metal particles can be measured in the form of a dispersion of particles. The scatter of the irradiated laser light is recorded in various spatial directions and evaluated in accordance with the Fraunhofer diffraction theory by means of the in connection with a HELOS or CILAS apparatus according to the manufacturer's instructions. The particles are treated computationally as spheres. Thus, the determined diameters always relate to the equivalent spherical diameter averaged over all spatial directions, irrespective of the actual shape of the metal particles. The size distribution which is calculated in the form of a volume average (relative to the equivalent spherical diameter) is determined. This volume-averaged size distribution can be represented inter alia as a cumulative frequency curve, which is also called the cumulative frequency distribution. For simplification, the cumulative frequency curve in turn is usually characterized by particular characteristic values, e.g. the D50 or D90 value. By a D90 value is meant that 90% of all the particles lie below the indicated value. In the case of a D50 value, 50% of all the particles lie below the indicated value.

The particle diameter is used to determine in particular the specific surface area of the individual particle and therefore also of the entire powder. The specific surface area designates the external surface area relative to the weight, which describes the surface area per kilogram of the powder and is defined as follows:

$${S}_{M} = \frac{Surface area}{Weight} [ \frac{{m}^{2}}{kg} ]$$

For an ideal sphere with the particle diameter d_{P}, the specific surface area accordingly is

$${S}_{M} = \frac{6}{{d}_{P} * ρ} [ \frac{{m}^{2}}{kg} ]$$

It is known in the literature that nanoparticles, i.e. particles with three dimensions of less than 100 nm, are characterized by a reduced melting point compared with the macromaterial. Such nanoparticles have a very high surface area in relation to their volume. That is to say that far more atoms lie on their surface than in the case of larger particles. Since atoms on the surface have fewer binding partners available to them than atoms in the core of the particle, such atoms are very reactive. For this reason they can interact with particles in their immediate environment to a considerably higher degree than is the case with macroparticles.

Since essentially the surface of the particles reacts with the plasma, a person skilled in the art knows that the increased surface area of smaller particles as a rule results in a significantly better melting behavior of the particles.

For uses in which higher melting metals and ceramic particles must be used, a person skilled in the art therefore uses particles with a small diameter. A disadvantage of such powders with a low particle diameter, however, is that they can be fluidized only with difficulty, as a result of which conveying of them is also made difficult. However, good conveyability is absolutely necessary for the industrial use of the coating by means of cold atmospheric plasma.

An advantageous device known to a person skilled in the art for applying a coating of particles is characterized in that the device comprises a jet generator with an inlet for the feed of a flowing working gas and an outlet for a plasma jet guided by the working gas, the jet generator has two electrodes, which can be connected to an alternating voltage or a pulsed direct voltage source, for formation of a discharge zone along which the working gas is guided, the jet generator has a feed opening which opens in the region of the discharge zone and via which particles, preferably platelet-shaped particles, can be fed to the plasma jet.

Ionizable gases, in particular pressurized air, nitrogen, argon, carbon dioxide or hydrogen, are fed to the device via the inlet as working gas. The working gas is purified beforehand, with the result that it is free from oil and lubricant. The gas stream in a conventional jet generator is between 10 and 70 l/min, in particular between 10 and 40 l/min, at a speed of the working gas of between 10 and 100 m/s, in particular between 10 and 50 m/s.

The jet generator further comprises two electrodes, in particular arranged coaxially at a distance from one another, which are connected to an alternating voltage source, but in particular a pulsed direct voltage source. The discharge zone forms between the electrodes. The pulsed direct voltage of the direct voltage source is preferably between 500 V and 12 kV. The pulse frequency lies between 10 and 100 kHz, but in particular between 10 and 50 kHz.

On the basis of the pulsed operation of the direct voltage source, it is to be assumed that no thermal equilibrium can form between the light electrons and the heavy ions. This results in a low temperature load of the platelet-shaped particles fed in. The coating process with the jet generator according to the invention is preferably controlled such that the plasma jet of the low temperature plasma has a gas temperature in the core zone of less than 900 degrees Celsius, but in particular of less than 500 degrees Celsius (low temperature plasma).

Since the feed opening opens in the region of the discharge zone between the electrodes of the jet generator, the particles arrive in a region in which a direct plasma excitation by the plasma jet takes place. The introduction of energy into the powder is maximized by this measure.

Preferably, the feed opening is located directly adjacent to the outlet for the plasma jet in the region of the discharge zone.

If the feeding in however takes place below the outlet of the device, which in principle is also possible, an indirect plasma excitation by the gas-guided plasma jet merely occurs, which is less favorable in terms of energy.

When used industrially, the position where the powder is fed into the plasma flame and the position where the powder is held available are spatially separated. Industrial operation requires certain amounts of powder to be held available, since otherwise, for example, an approximately continuous coating process is not feasible because of the times needed for replenishing the powder. Storage in a very close location is not feasible for technical reasons. The powder must therefore be conveyed over a certain distance. This explains the need to use powders with a good conveyability.

However, powders with small particle diameters do not have such a good conveyability. As described, however, such small particle diameters must be used for certain uses in which high-melting materials are used. In order nevertheless to make possible a conveying of such powders, novel conveying units have been developed in the state of the art. For this, for example, vibrations are introduced into the powder, or the powder is swirled up in vortex chambers and then conveyed. A conveying of fine powders is possible in principle by means of such special conveying units. However, the conveying units have disadvantages. On the one hand these are expensive in terms of apparatus, with the result that they have to undergo frequent maintenance. On the other hand they often require expensive control engineering. Furthermore, in each case they require larger amounts of energy, as a result of which they significantly impair the profitability of the overall process. For this reason improvements in the conveying units are being worked on intensively.

The inventors have now found, completely surprisingly, that these conveying difficulties can be avoided by sheathing the powder particles with an enclosing polymer shell, without the properties of the deposited layer being adversely influenced.

It is known to a person skilled in the art that an improvement in the flow properties is possible by the application of modifications to the surface. However, a person skilled in the art avoids a coating of powder for use in coating methods with cold plasma. As described, the use, and the requirements thereof, determines the material type of the powder. This means that a person skilled in the art regards changes to the powder as a disadvantage, since in principle they lead to changes in the chemical composition of the powder and therefore in the layer that forms. In particular, a person skilled in the art must assume that changes to the powder, as impurities in the layer, will influence the properties thereof.

The inventors have now found, surprisingly, that a modification of the powder with an enclosing polymer shell improves the conveyability without influencing the properties of the layer. In particular, the inventors have found, surprisingly, that the enclosing polymer shell is no longer present in the deposited layer, with the result that the quality of the layer is not influenced.

By the method according to the invention it is therefore possible to modify powders with poor conveyability by application of an enclosing polymer shell such that a good conveyability can be achieved without having to undertake an expensive optimization of conveying units. As a result, the method according to the invention provides the advantage over the state of the art that it is possible to use, on existing installations, powders with particle sizes which are not to be conveyed with the powder conveyer found in the installation without the coating applied according to the invention. Since application of the enclosing polymer shell is possible on almost all powder materials, the method according to the invention represents a great advantage.

The particles of the method according to the invention enclosed by a polymer shell are characterized in that the particles of the powder are enclosed by a closed shell of a crosslinked polymer. The use of a crosslinked polymer results in the advantage that the layer thickness of the enclosing shell can be minimized, since the density of the polymer shell is maximized.

The average thickness of the enclosing shell is less than 2 μm, preferably less than 500 nm, particularly preferably less than 300 nm, quite particularly preferably less than 200 nm. The average thickness, on the other hand, is a minimum of 3 nanometers (nm), preferably 5 nm, particularly preferably 10 nm, quite particularly preferably 15 nm.

For determination of the thickness of the enclosing polymer shell, no measuring apparatuses which can easily determine this value exist in the state of the art. A determination is therefore carried out as standard by determination of the thickness of the shell of a statistically sufficiently high number of particles enclosed by a polymer shell in SEM (scanning electron microscope) analyses. For this, the particles are dispersed, for example, in a varnish and this is then applied to a film. The film coated with the varnish containing particles enclosed in a polymer shell is then cut with a suitable tool with the result that the cut runs through the varnish. The prepared film is then introduced into the SEM such that the direction of observation is directed perpendicular to the cut edge. In this way the particles are mostly viewed from their side, with the result that the thickness of the polymer layer can easily be determined.

The determination is carried out as standard via marking of the corresponding boundaries by means of a suitable tool, such as the software packages included by the manufacturer as standard with the SEM apparatuses. For example, the determination can be carried out by means of an SEM apparatus of the Leo series from the manufacturer Zeiss (Germany) and the software Axiovision 4.6 (Zeiss, Germany). The thickness of the polymer shell enclosing the particles is, of course, not homogeneous over all the particles. The range of variation of the polymer layer can be +/−50% of the average thickness.

The polymer layer can in principle consist of all of the organic polymers known to a person skilled in the art. Preferably, it consists of polymerized plastic resin. It particularly preferably consists of polymerized acrylate resin. The polymer shell quite particularly preferably consists of polyacrylate or polymethacrylate. Synthetic resin coatings consisting of e.g. epoxides, polyesters, polyurethanes or polystyrenes and mixtures thereof can of course also be used.

By an enclosed polymer shell within the meaning of the invention is meant a polymer coating of a polymer, in particular a synthetic resin, which is built up of a single layer, i.e. not of several detectable sub-structures. In the context of the invention the designation crosslinked polymer shell means that the proportion of monomers, or molecules which are not crosslinked with one another, in the shell is less than 20 wt. %, preferably less than 15 wt. %, particularly preferably less than 10 wt. % of the total weight of the shell.

According to a preferred development of the invention the polymer coating was carried out by direct polymerization of the monomers onto the particles.

The shell can be built up of one or more monomer units. Preferably, it is built up of at least two monomer units. The monomer units are preferably acrylate or methacrylate groups, which are characterized in that they have at least two functional acrylate or methacrylate groups. Preferably, the shell additionally comprises organofunctional silane in addition to the acrylate or methacrylate groups.

In addition to acrylate and/or methacrylate compounds, further monomers and/or polymers can also be present in the synthetic resin coating of the metal effect pigments according to the invention. Preferably, the proportion of acrylate and/or methacrylate compounds, including organofunctional silane, is at least 70 wt. %, further preferably at least 80 wt. %, still further preferably at least 90 wt. %, in each case relative to the total weight of the synthetic resin coating. According to a preferred variant, the synthetic resin coating is built up exclusively of acrylate and/or methacrylate compounds and one or more organofunctional silanes, wherein the synthetic resin coating can additionally also contain additives, such as corrosion inhibitors, colored pigments, dyestuffs, UV stabilizers, etc. or mixtures thereof.

It is preferred according to the invention that the acrylate and/or methacrylate starting compounds with several acrylate groups and/or methacrylate groups have in each case at least three acrylate and/or methacrylate groups. Furthermore preferably, these starting compounds can in each case also have four or five acrylate and/or methacrylate groups.

The use of polyfunctional acrylates and/or methacrylates allows the provision of metal effect pigments with a very good resistance to chemicals and a higher electrical resistance. The metal effect pigments according to the invention prepared using polyfunctional acrylates and/or methacrylates are electrically non-conductive, which extends the possible uses of metal effect pigments considerably. Using the metal effect pigments according to the invention, it is consequently possible to apply metal effect varnishes to objects which must be electrically non-conductive, such as, for example, protective housings, insulators, etc.

It has been shown, surprisingly, that two or three acrylate and/or methacrylate groups per acrylate and/or methacrylate starting compound in combination with an organofunctional silane are already sufficient to produce on the metal effect pigment a synthetic resin layer which is extremely resistant to chemicals and is electrically non-conductive.

The synthetic resin layer surprisingly has, in particular with 2 to 4 acrylate and/or methacrylate groups per acrylate and/or methacrylate starting compound, an exceptional density and strength, without being brittle. 3 acrylate and/or methacrylate groups per acrylate and/or methacrylate starting compound have proved to be extremely suitable. These mechanical properties, which are valuable in combination, make it possible also to expose the metal effect pigments according to the invention to high shearing forces, for example during pumping through pipelines, such as in a closed circular pipeline, without damage or detachment of the synthetic resin layer from the metal effect pigment surface occurring.

According to a further preferred embodiment, the weight ratio of polyacrylate and/or polymethacrylate to organofunctional silane is from 10:1 to 0.5:1. Furthermore preferably, the weight ratio of polyacrylate and/or polymethacrylate to organofunctional silane lies in a range of from 7:1 to 1:1.

It has been shown that a deficit, based on the weight, of organofunctional silane with respect to polyacrylate and/or polymethacrylate is also sufficient for application of a synthetic resin layer which adheres firmly to the metal effect pigment surface and at the same time is resistant to chemicals or highly corrosive ambient conditions.

According to a preferred embodiment of the invention, the metal effect pigments of the present invention have a coating which is built up of at least two monomer components a) and b), wherein a) is at least one acrylate and/or methacrylate and b) is at least one organofunctional silane, which preferably has at least one functionality that is radically polymerizable.

Component a) preferably comprises polyfunctional acrylates and/or methacrylates, wherein the corresponding monomers have di-, tri- or polyfunctional acrylate and/or methacrylate groups.

Examples of suitable difunctional acrylates a) are: allyl methacrylate, bisphenol A dimethacrylate, 1,3-butanediol dimethacrylate, 1,4-butanediol dimethacrylate, ethylene glycol dimethacrylate, 1,6-hexanediol diacrylate, 1,6-hexanediol dimethacrylate, diethylene glycol dimethacrylate, diurethane dimethacrylate, dipropylene glycol diacrylate, 1,12-dodecanediol dimethacrylate, ethylene glycol dimethacrylate, methacrylic anhydride, N,N-methylene-bis-methacrylamide, neopentyl glycol dimethacrylate, polyethylene glycol dimethacrylate, polyethylene glycol 200 diacrylate, polyethylene glycol 400 diacrylate, polyethylene glycol 400 dimethacrylate, tetraethylene glycol diacrylate, tetraethylene glycol dimethacrylate, tricyclodecane dimethanol diacrylate, tripropylene glycol diacrylate, triethylene glycol dimethacrylate or mixtures thereof.

According to the invention e.g. pentaerythritol triacrylate, trimethylolpropane triacrylate, trimethylolpropane trimethacrylate, tris-(2-hydroxyethyl) isocyanurate triacrylate, pentaerythritol tetraacrylate, dipentaerythritol pentaacrylate or mixtures thereof can be used as acrylates of higher functionality.

Trifunctional acrylates and/or methacrylates are particularly preferred.

Dipentaerythritol pentaacrylate, pentaerythritol triacrylate, pentaerythritol tetraacrylate, trimethylolpropane triacrylate, trimethylolpropane trimethacrylate, tris-(2-hydroxyethyl) isocyanurate triacrylate, 1,6-hexanediol dimethacrylate or mixtures thereof have proved to be very suitable acrylates in the present invention.

According to the invention, for example, (methacryloxymethyl)methyldimethoxysilane, methacryloxymethyltrimethoxysilane, (methacryloxymethyl)methyldiethoxysilane, methacryloxymethyltriethoxysilane, 2-acryloxyethylmethyldimethoxysilane, 2-methacryloxyethyltrimethoxysilane, 3-acryloxypropylmethyldimethoxysilane, 2-acryloxyethyltrimethoxysila[pi], 2-methacryloxyethyltriethoxysilane, 3-acryloxypropyltrimethoxysilane, 3-acryloxypropyltripropoxysilane, 3-methacryloxypropyltriethoxysilane, 3-methacryloxypropyltrimethoxysilane, 3-methacryloxypropyltriacetoxysilane, 3-methacryloxypropylmethyldimethoxysilane, vinyltrichlorosilane, vinyltrimethoxysilane vinyldimethoxymethylsilane, vinyltriethoxysilane, vinyltris(2-methoxyethoxy)silane, vinyltriacetoxysilane or mixtures thereof can be used as organofunctional silanes b).

Acrylate- and/or methacrylate-functional silanes are particularly preferred.

In certain embodiments of the present invention the organofunctional silane is preferably selected from the group consisting of 2-methacryloxyethyltrimethoxysilane, 2-methacryloxyethyltriethoxysilane, 3-methacryloxypropyltriethoxysilane, 3-methacryloxypropyltrimethoxysilane, (methacryloxymethyl)methyldimethoxysilane, vinyltrimethoxysilane and mixtures thereof.

The abovementioned compounds and further suitable monomers which can be used in the present invention are obtainable, for example, from Degussa AG, Frankfurt, Germany; Röhm GmbH & Co. KG, Darmstadt, Germany; Sartomer Europe, Paris, France; GE Silicons, Leverkusen, Germany or Wacker Chemie AG, Munich, Germany.

The synthetic resin layer of the particles preferably to be used according to the invention, preferably metal effect pigments, preferably has an average layer thickness in a range of from 20 nm to 200 nm, further preferably from 30 nm to 100 nm. According to a further variant of the invention, the average layer thickness lies in a range of from 40 to 70 nm. Astonishingly, in the metallic particles preferably to be used according to the invention, preferably metal effect pigments, extremely low average layer thicknesses are sufficient to reliably protect the metal cores of these pigments which are very sensitive to aggressive ambient conditions. In particular, with the average layer thicknesses indicated no noticeable impairment of the gloss or color of the metal cores by the synthetic resin layer occurs.

For production of the polymer shell, the powder particles are preferably first pre-coated with a silane, carrying a functional group, which serves as an adhesion promoter for the polymer shell. The functional group is particularly preferably acrylate or methacrylate groups.

According to one embodiment of the invention the powder has particles with a size distribution with a D50 value from a range of from 1 to 150 μm to. According to a further preferred embodiment the size distribution is between 1.5 μm and 100 μm. According to a very preferred embodiment it is between 2 μm and 50 μm. The measurements can be carried out, for example, with the HELOS particle size analyzer from Sympatec GmbH, Clausthal-Zellerfeld, Germany. The dispersing of a dry powder can be carried out here using a dispersing unit of the Rodos T4.1 type under a primary pressure of, for example, 4 bar. Alternatively, the size distribution curve of the particles can be measured, for example, with an apparatus from Quantachrome (apparatus: Cilas 1064) according to the manufacturer's instructions. For this, 1.5 g of the particles are suspended in approx. 100 ml isopropanol, treated for 300 seconds in an ultrasound bath (apparatus: Sonorex IK 52, Bandelin) and then introduced by means of a Pasteur pipette into the sample preparation cell of the measuring apparatus and measured several times. The resulting mean values are formed from the individual measurement results. The scattered light signals are evaluated according to the Fraunhofer method.

The material of which the powder consists can be a metal, a non-metal, a polymer or an oxide.

Preferably, the material is a metal or a mixture of at least two metals or an alloy consisting of at least two metals. The purity of the individual metals is preferably more than 70 wt. %, further preferably more than 90 wt. %, particularly preferably more than 95 wt. %, in each case relative to the total weight of the metal, the alloy or mixture. For the preparation of the powders, the metal, the metal mixture or metal alloy can, for example, be melted under the action of heat and then converted into the powder by atomizing or by application to rotating components. Metallic powders or metal powders produced in this way have, for example, a particle size distribution with an average size (D50 value) in the range of from 1 to 100 μm, preferably from 2 to 80 μm. The particle or grain shape of the metallic powder produced is preferably approximately spherical. However, the powder can also have particles which are irregular in shape and/or are present in the form of needles, rods, cylinders or platelets.

In the case of metallic particles, these can consist, for example, of aluminum, zinc, tin, titanium, iron, copper, silver, gold, tungsten, nickel, lead, platinum, silicon, further alloys or mixtures thereof. According to one variant of the method according to the invention, aluminum, copper, zinc and tin or alloys or mixtures thereof are particularly preferred.

In the case of non-metallic particles, these can consist, for example, of oxides or hydroxides of the metals already mentioned or of other metals, furthermore the particles can consist of glass or sheet silicates, such as mica or bentonites. In addition, the particles can consist of carbides, silicates, nitrides, phosphates and sulfates. Particles which are suitable for the method can also be obtained and prepared by other routes (e.g. synthetically by means of crystallization, growing, etc., see growing methods, or with the aid of conventional ore digging and flotation, among other things).

The particles can also be organic and inorganic salts. The particles can furthermore consist of pure or mixed homo-, co-, block or pre-polymers or plastics or mixtures thereof, but can also be organic pure or mixed crystals or amorphous phases.

The particles can also consist of mixtures of at least two materials, wherein in principle all mixing ratios of the two materials are possible. Preferably, the amount of the material contained in the lowest amount by weight is more than 2 percent by weight, relative to the total weight of the particles.

During the coating process in principle layers with a packing density which is as high as possible are to be produced, since in most cases these have ideal use properties. A packing density which is as high as possible is synonymous with a layer which is as similar as possible to a closed, non-particulate layer, accordingly a layer which corresponds to the ideal base material. Such layers are sought, since they have the best physical and chemical properties. Thus, for example, strip conductors of silver show an increasing resistance when the packing density decreases.

A low packing density results, on the other hand, specifically when the particles retain their shape and structure, as far as possible, during the coating process, and in particular are still present as individual particles in the layer that forms. If anything, the particles tend to show such a behavior if they consist of higher-melting metals (melting point >500° C.) and non-metallic material. The energy of the plasma activates such particles only on their surface, as a result of which the shape of the particles persists as such in the layer that forms on the substrate.

The method according to the invention can be used for coating a large number of substrates. Substrates can be, for example, metals, wood, plastics or paper. The substrates can be present in the form of geometrically complex shapes, such as components or finished products, but also as a film or sheet.

The uses for the method according to the invention are likewise very diverse. For example, layers for applications for the production of optically and electromagnetically reflecting or absorbent, electrically conductive, semiconducting or insulating layers, diffusion barriers for gases and liquids, sliding layers, wear and corrosion protection layers and layers for influencing surface tension as well as adhesion promotion can be produced using the method.

Conductive layers which are produced by the method can be used, for example, to produce heating strip conductors which are used for heating substrates. Such conductive layers can furthermore also be used as shielding, as an electrical contact and as an antenna, in particular RFID (radio frequency identification) antennae. Sensor surfaces (e.g. for HMI interfaces, operating panels, etc.)

EMC/EMI shielding applied to cable/housing, etc.
Electrical contacting generally over various materials.
Encapsulation (e.g. populated wafers)

The layers can be applied in the form of planar layers which cover the substrate in a planar form and in large part, preferably greater than 70% of the surface of the substrate. The layers can also be applied in the form of patterns, which are preferably matched to the desired functionality. The production of geometric patterns can also be carried out, for example, by the use of masks.

The device for carrying out the method is explained in more detail below with the aid of the figures. There are shown in:

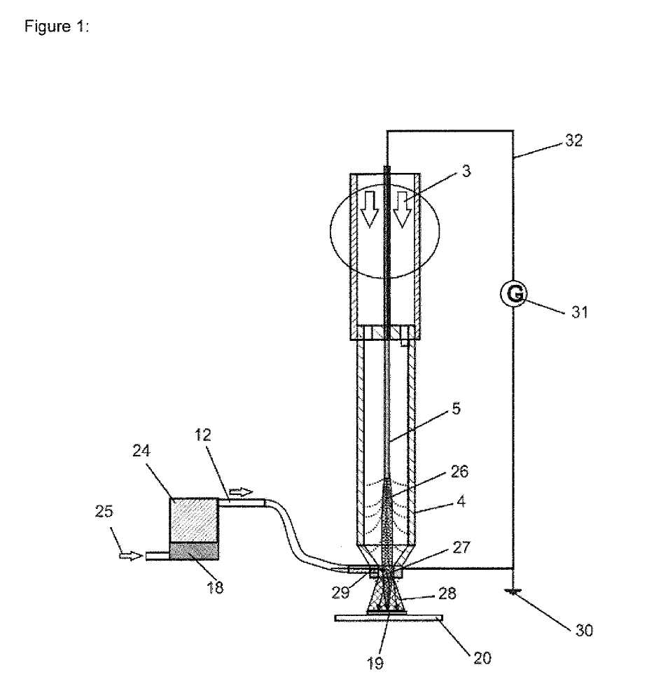

FIG. 1 a schematic representation of an embodiment example of a jet generator according to the invention and

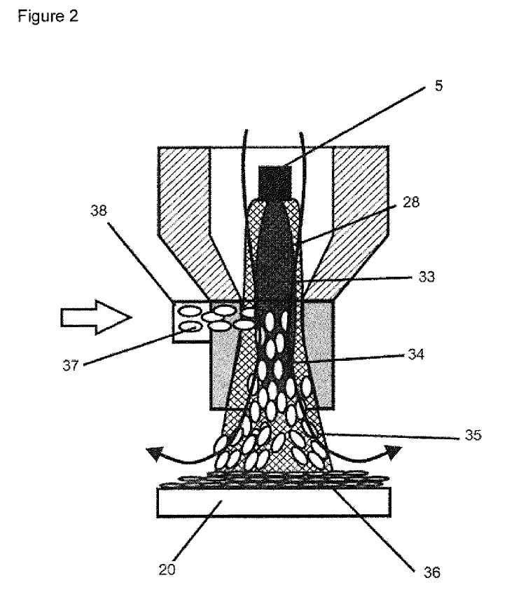

FIG. 2 an enlarged representation of the jet generator according to FIG. 1 in the region of the outlet.

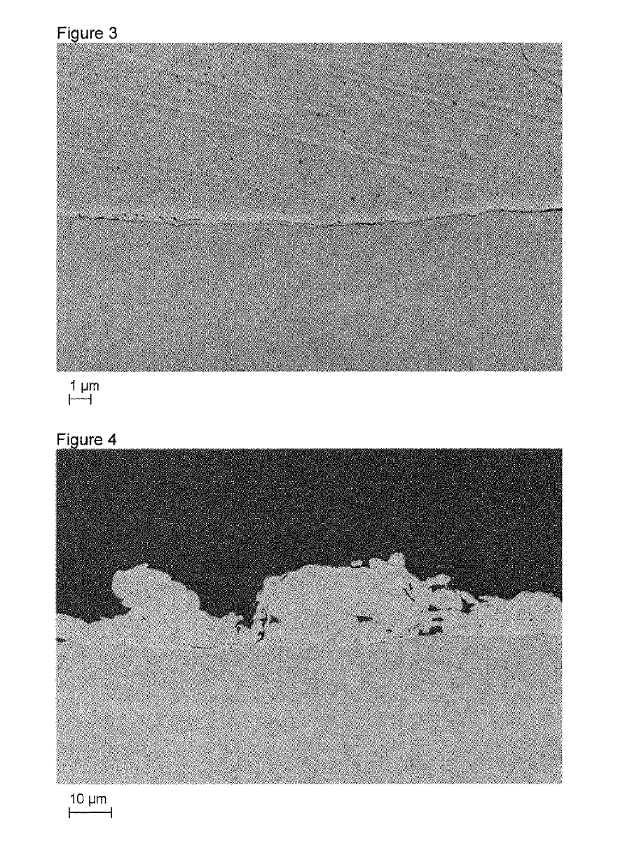

FIGS. 3 and 4 SEM photographs of a copper layer applied to a steel sheet.

The jet generator (1) according to the invention for generating a plasma jet (2) of a low temperature plasma comprises two electrodes (4, 5) arranged in the stream of a working gas (3) and a voltage source (6) for generating a pulsed direct voltage between the electrodes (4, 5). The first electrode (4) is designed as a pin electrode, while the second electrode (5), arranged at a distance therefrom, is formed as an annular electrode. The zone between the tip of the pin electrode (4) and the annular electrode (5) forms a discharge zone (16).

A jacket (7) of electrically conductive material is arranged concentrically to the pin electrode (4) and is insulated from the pin electrode (4). The working gas (3) is fed via an inlet (21) to the front face of the jet generator (1) opposite the annular electrode (5). The inlet (21) is located on a casing (22) of electrically insulating material mounted on a front face on the hollow cylindrical jacket (7) and holding the pin electrode (4). On the opposite front face the jacket (7) narrows in the form of a nozzle to an outlet (8) for the plasma jet (2).

Immediately adjacent to the outlet (8) running in the axial direction of the jet generator (1), abeam of the longitudinal extension thereof, there is a feed opening (9), via which platelet-shaped particles (10) can be fed to the plasma jet (2). The feed opening (9) of the jet generator is connected for this purpose via a line (12) to a vortex chamber (11) in which platelet-shaped particles (10) are stored. The vortex chamber (11) is filled with the platelet-shaped particles (10) at most up to a maximum filling level (13). Below the maximum filling level (13) an inlet (23) opens into the vortex chamber (11) for a carrier gas (14), which is blown into the particle reservoir under a pressure which is increased compared with the ambient pressure. By this means the particles (10) are swirled up in the space above the maximum filling level (13) and enter the discharge zone (16) of the jet generator (1) via an outlet (15), the line (12) and the feed opening (9).

As can be seen in particular from the enlargement in FIG. 2, the platelet-shaped particles (10) enter, at right angles to the direction of propagation of the plasma jet (2), a core zone (17) of the plasma jet (2) in which a temperature of less than 500 degrees Celsius prevails (low temperature plasma).

The voltage source (6) increases, during each pulse, the voltage applied between the electrodes (4, 5) until the ignition voltage for formation of an arc between the electrodes (4, 5) is applied between the electrodes (4, 5). Due to the conductive jacket (7), discharges also occur in the direction of the inner jacket surface, as is indicated by the broken lines in FIG. 1. When the ignition voltage is reached, the discharge zone (16) between the electrodes (4, 5) becomes conductive. The voltage source (6) is preferably formed such that it generates a voltage pulse with an ignition voltage for the arc discharge and a pulse frequency which in each case lets the arc extinguish between two successive voltage pulses. As a result, a pulsed gas discharge occurs in the plasma jet (2). The pulse frequency preferably lies in a range of between 10 kHz and 100 kHz, in the embodiment example shown at 50 kHz. The voltage of the voltage source is a maximum of 12 kV. Compressed air is used as the working gas (3), wherein in the normal operating state 40 l/min is fed in.

If in deviation from the embodiment example shown not only a punctiform coating is to be produced on the substrate (20) with the aid of the jet generator (1), in one embodiment of the invention there is the possibility that the plasma jet (2) and the substrate (20) are moved relative to one another at least from time to time during the application of the coating. The relative movement can be carried out by displacing the substrate (20), for example on a bench which can be moved in the horizontal plane. Alternatively, the jet generator (1) is arranged on a travelling unit which can be moved at least in a plane parallel to the substrate (20), with the result that the generator can be moved relative to the substrate at a defined speed. By the relative movement, tracks or also coatings over the whole surface of the substrate can be produced.

List of reference numbers:

| No. | Designation |
|---|---|
| 1 | Jet generator |
| 2 | Plasma jet |
| 3 | Working gas |
| 4 | Electrode |
| 5 | Electrode |
| 6 | Voltage source |
| 7 | Jacket |
| 8 | Outlet |
| 9 | Feed opening |
| 10 | Particles |
| 11 | Vortex chamber |
| 12 | Line |
| 13 | Maximum filling level |
| 14 | Carrier gas |
| 15 | Outlet |
| 16 | Discharge zone |
| 17 | Core zone |
| 18 | Powder |
| 19 | Coating |
| 20 | Substrate |
| 21 | Inlet, working gas |
| 22 | Casing |
| 23 | Inlet, carrier gas |
| 24 | Powder-gas mixture |
| 25 | Conveying gas |
| 26 | Core region of the discharge/ |
| | plasma space |
| 27 | Feed region |
| 28 | Plasma |
| 29 | Nozzle |
| 30 | Earth connection |
| 31 | Generator |
| 32 | Electrical lead |
| 33 | Core zone, plasma |
| 34 | Activated particles |
| 35 | Atmospheric plasma |
| 36 | Layer |
| 37 | Particles |
| 38 | Feed line |

### EMBODIMENT EXAMPLES

The present invention is illustrated with the aid of the following examples, but without being limited thereto.

### Measurement Methods Used:

### Particle Size:

The particle size was determined using a Giles 1064 apparatus using the standard measurement software.

### Example 1

### Preparation of Ball-Shaped (Spherical) Aluminum Powder

Approx. 2.5 t of aluminum bars (metal) were introduced continuously into an induction crucible furnace (Induga, Cologne, Germany) and melted. In the so-called forehearth the aluminum melt was present in liquid form at a temperature of about 720° C. Several nozzles which operate according to an injector principle were immersed into the melt and atomized the aluminum melt vertically upwards. The atomizing gas was compressed to 20 bar in compressors (Kaeser, Coburg, Germany) and heated up to about 700° C. in gas heaters. The aluminum powder formed after the spraying/atomizing solidified and cooled in flight. The induction furnace was integrated into a closed installation. The atomization was carried out under an inert gas (nitrogen). The aluminum powder was first deposited in a cyclone, wherein the pulverulent aluminum grit deposited there had a D50 of 14-17 μm. A multicyclone subsequently served for further deposition, wherein the pulverulent aluminum powder deposited in this had a D50 of 2.3-2.8 μm. The gas-solid separation was carried out in a filter (Alpine, Thailand) with metal elements (Pall). Here an aluminum powder with a d10 of 0.7 μm, a d50 of 1.9 μm and a d90 of 3.8 μm was obtained as an extra-fine fraction.

### Example 2

### Preparation of Metallic Platelet-Shaped Particles by Grinding

4 kg of glass beads (diameter: 2 mm), 75 g of extra-fine aluminum powder, 200 g of white spirit and 3.75 g of oleic acid were introduced into a jar mill (length: 32 cm, width: 19 cm). The mixture was then ground at 58 rpm for 15 h. The product was separated from the grinding beads by rinsing with white spirit and then sieved in a wet sieving operation on a 25-μm sieve. The fine grain was largely freed from white spirit via a suction filter (approx. 80% solids content).

### Example 3

### Preparation of Non-Metallic Platelet-Shaped Particles (Aluminum Hydroxide) by Oxidation of Metallic Platelet-Shaped Particles (Aluminum)

300 g of an aluminum powder shaped as described in Example 2 was dispersed in 1,000 ml isopropanol (VWR, Germany) in a 5-l glass reactor by stirring with a propeller stirrer. The suspension was heated to 78° C. 5 g of a 25 wt. % ammonia solution (VWR, Germany) was then added. After a short time a vigorous gas formation was to be observed. Three hours after the first addition of ammonia a further 5 g of 25 wt. % ammonia solution was added. After a further three hours 5 g of 25 wt. % ammonia solution was again added. The suspension was stirred further overnight. The next morning the solid was separated off by means of a suction filter and dried in a vacuum drying cabinet at 50° C. for 48 h. A white powder was obtained. This powder was then characterized. The particle size and the zeta potential as a function of the pH were first investigated. The pH was adjusted by means of 1.0 M NaOH or 1.0 M HCl. The results are shown in FIG. 2. At a low and also at a high pH the zeta potential shows a maximum and the particle diameter shows a minimum. An XRD analysis of the material is shown in FIG. 3. From this, a composition of approx. 33 wt. % boehmite (AlOOH) and 67 wt. % gibbsite (Al(OH)₃) can be deduced.

### Example 4

### Preparation of Non-Metallic Platelet-Shaped Particles (Aluminum Oxide) by Heat Treatment of Non-Metallic Platelet-Shaped Particles (Aluminum Hydroxide)

500 g of a material prepared according to Example 3 was heated to 1,100° C. in a rotary tube furnace (Nabertherm, Germany) for 10 minutes. 335 g of a white powder was obtained. This was investigated as described. The results are shown in FIGS. 4 and 5. In contrast to the uncalcined material, the particle diameter is somewhat greater and the zeta potential is positive in the entire pH range. The XRD analysis shows theta-Al₂O₃.

### Example 5-8

### Coating of Particles with an Acrylate Shell

The materials prepared in Examples 1-4 were enclosed by a shell of a crosslinked acrylate in a further step. The following batch quantities were used.

| Designation | Starting material | Solvent | Product composition |
|---|---|---|---|
| Example 5 | Example 1 | ethanol | 6.6 g |
| | (aluminum grit) | | polymer coating |
| | | | 93.4 g |
| | | | aluminum grit |
| Example 6 | Example 2 | ethanol | 6.3 g |
| | (platelet-shaped | | polymer coating |
| | aluminum) | | 93.7 g |
| | | | platelet-shaped |
| | | | aluminum |
| Example 7 | Example 3 | ethanol | 6.1 g |
| | non-metallic | | polymer coating |
| | platelet-shaped | | 93.9 g non-metallic |
| | particles | | platelet-shaped |
| | | | particles |
| Example 8 | Example 4 | ethanol | 6.2 g |
| | non-metallic | | polymer coating |
| | platelet-shaped | | 93.8 g non-metallic |
| | particles | | platelet-shaped |
| | | | particles |

In each case 100 g of the product from Examples 1-4 was dispersed in 525 g ethanol such that a 16 wt. % dispersion formed. 0.65 g methacryloxypropyltrimethoxysilane (MEMO) was then added and the mixture was stirred at 25° C. for 1 h and at 75° C. for 3 h. 100 ml of a solution of 6 g trimethylolpropane trimethacrylate (TMPTMA) and 0.6 g dimethyl 2,2′-azobis(2-methylpropionate) (trade name V 601; obtainable from WAKO Chemicals GmbH, Fuggerstraβe 12, 41468 Neuss) in ethanol were subsequently metered in at 78° C. over 5 h. Stirring followed at 72° C. for 16 h, the reaction mixture filtered off and isolated as a paste. The pastes obtained were dried under vacuum with a gentle stream of inert gas at 100° C. and then sieved with a 71-μm mesh width.

### Example 9

### Preparation of Metallic Particles Coated with Polyacrylate

Tin particles or copper particles in paste form were dispersed in 600 g ethanol for the preparation of a 35 wt. % dispersion. 100 ml of a solution of 0.5 g dimethyl 2,2′-azobis(2-methylpropionate) (trade name V 601; obtainable from WAKO Chemicals GmbH, Fuggerstraβe 12, 41468 Neuss), 1 g methacryloxypropyltrimethoxysilane (MEMO) and 10 g trimethylolpropane trimethacrylate (TMPTMA) in white spirit were subsequently metered in over a period of 1 h. Stirring followed at 75° C. for a further 15 h, the reaction mixture was filtered off, isolated as a paste and dried under reduced pressure.

| Example | Metal | D₅₀ |
|---|---|---|
| 9-1 | copper grit | 25 μm |
| 9-2 | copper flakes | 35 μm |
| 9-3 | copper grit | 9 μm |
| 9-4 | tin grit | 28 μm |

### Example 10

### Low Temperature Plasma Coating

The coated particles were applied by means of a Plasmatron installation from Inocon, Attnang-Puchheim, Austria, wherein argon and nitrogen were used as ionizable gases. Standard process parameters were used here.

Examples 9-1 to 9-4 were applied to alu sheets, steel sheets and wafers. A very uniform application of the powder, a low overspray, a good adhesion of the layer to the surface and a color of the coating which leads to the conclusion that there is a small amount of oxidation were shown here. This was also confirmed in subsequent SEM photographs. Examples of photographs of the coating with spherical copper grit according to Example 9-1 are to be found in FIGS. 3 and 4. The excellent binding to the surface, for example, can be seen from FIG. 3. FIG. 4 shows the surprisingly uniform distribution of the individual particles in relation to the size of the individual particles (D₅₀=25 μm).

Attempts to apply uncoated particles by means of the installation for coating using a low temperature plasma resulted in no usable coatings. In particular, no cohesive coating was to be achieved by this means. Agglomerates that arose on the surface showed no noticeable binding to the substrate surface.

1. A method for applying a coating to a substrate using cold plasma, wherein the method comprises:
(a) introducing particles comprising a polymer coating into a cold plasma which is directed onto a substrate to be coated and has a plasma temperature of less than 3,000 K, and
(b) depositing the particles activated in the cold plasma in step (a) on the substrate.

2. The method according to claim 1, wherein the cold plasma is generated in a coating nozzle and the particles are introduced into the coating nozzle via a carrier gas, wherein the coating nozzle and the substrate are movable relative to one another.

3. The method according to claim 1, wherein the average layer thickness of the polymer coating is less than 2 μm.

4. The method according to claim 1, wherein the cold plasma is generated under the application of a pulsed direct voltage or alternating voltage to an ionizable gas.

5. The method according to claim 1, wherein the particles are platelet-shaped particles.

6. The method according to claim 2, wherein the carrier gas is passed through a container, in which the particles are stored as a powder, at a flow rate such that the powder is at least partially swirled up, a powder dust being generated, and the generated powder dust is introduced into the coating nozzle.

7. The method according to claim 2, wherein the carrier gas flows through the coating nozzle with a volume flow from a range of from 1 Nl/min to 15 Nl/min.

8. The method according to claim 1, wherein the cold plasma is generated, and applied to the substrate, under a pressure which lies in a range of 0.5×10⁵-1.5×10⁵ Pa.

9. The method according to claim 1, wherein the average thickness of the polymer coating is less than 300 nm.

10. The method according to claim 1, wherein the polymer coating is a polymerized (meth)acrylate resin.

11. The method according to claim 1, wherein the particles are metal particles and the metals are selected from the group consisting of aluminum, zinc, tin, titanium, iron, copper, silver, gold, tungsten, nickel, lead, platinum, silicon, alloys thereof and mixtures thereof.

12. The method according to claim 1, wherein the particles coated with a polymer selected from the group consisting of oxides, carbides, silicates, nitrides, phosphates, sulfates and mixtures thereof.

13. The method according to claim 1, wherein the substrate is selected from the group consisting of metals, plastics, paper, biological materials, glass, ceramic and mixtures thereof.

14. A coating on a substrate, the coating being obtained by the method according to claim 1.

15. The coating according to claim 14, wherein the particles are platelet-shaped particles having a polymer coating with an average thickness of less than 2 μm.

16. The method according to claim 1, wherein the particles are at least partially intergrown with one another.

17. The method according to claim 1, wherein the polymer coating comprises at least one polymer selected from the group consisting of polyacrylates, epoxides, polyesters, polyurethanes, polystyrenes and mixtures thereof.

18. The method according to claim 1, wherein the polymer coating further comprises organofunctional silane.
